(19) United States
(12) Patent Application Publication
(10) Pub. No.: US 2002/0166687 A1
(43) Pub. Date: Nov. 14, 2002

(54) Encapsulation arrangement

(75) Inventors: Hakan Tornovist, Fredrikas Gard (SE); Sophia Johansson, Nordhemsgatan (SE)

Correspondence Address: Stanley R. Moore, Esq., Jenkens and Gilchrist, P.C., 3200 Fountain Place, 1445 Ross Ave., Dallas, TX, 75202, US

(73) Assignee: Telefonaktiebolaget LM Ericsson

(21) Appl. No.: 10/107,708

(22) Filed: Mar. 27, 2002

(30) Foreign Application Priority Data
Mar. 28, 2001 (SE) 0101107-1

(51) Int. Cl. H05K 5/06

(52) U.S. Cl. 174/52.2

(57) ABSTRACT

An encapsulation arrangement for encapsulating an electric component is arranged on a carrying structure. The encapsulation arrangement includes a plurality of expandable plastic particles. Each particle encapsulates a gaseous medium.

### TECHNICAL FIELD OF THE INVENTION

The present invention relates to a method and an encapsulation arrangement for encap- sulating an electric component arranged on a carrying structure.

### BACKGROUND OF THE INVENTION

To achieve a cost effective environmental protection when packaging electrical modules, especially microwave modules, a non-hermetic sealing can be used. Especially, a naked chip must be protected against mechanical stress, moisture and pollutions. Moreover, in case of microwave circuits, the material protecting the chip should not affect the microwave characteristics at high frequencies. It is also desired that the protective material does not cause high thermal expansion, so that the wire bonds, chip, and the substrate are affected mechanically.

It has also been observed that the commercially available protective material is not suitable for high frequency (e.g. over 1 GHz) applications. In particular, thermal mismatch is a problem when a large area, for example in Multichip Modules (MCMs), is encapsulated.

For protecting naked chips against environmental influences, traditionally so-called glob top technique is used. An encapsulant is dispensed to form a glob over the chip and the electrical interconnections, hence the term glob-top encapsulant. Glob-top encapsulation was originally introduced for consumer packages such as video games, but the demand for miniaturized circuitry led to the use of glob-top as the preferred assembly method for many types of products including smart credit cards, microprocessor circuitry, and complex hybrids. This encapsulation technology allows the manufacturer to make relatively thin devices, and many companies produce packages with cost equal to or less than conventional plastic packages.

Typical glob-top compositions include epoxy or silicone encapsulating resins, which provide protection against corrosion, vibration and mechanical stresses. The purpose of an encapsulant is to protect the chip and fragile wire bonds. An encapsulant should not create unusual stresses during thermal cycling, and it should protect the chip from mechanical shock, moisture, and various chemicals. Matching the coefficient of thermal expansion to the substrate and the chip is critical for long-term dimensional stability and proper sealing of leads to prevent penetration of moisture and ionic contaminants. Encapsulants must have low moisture absorption and be of high purity, i.e., a low level of ionic contaminants such as lithium, sodium, potassium, and chlorine ions. This is very important because ionic contaminants can result in corrosion of chip metallizations under conditions of high humidity. Another significant problem with glob-top is its high dielectric constant, which strongly affects the microwave characteristics at high frequencies.

Moreover, thermal mismatch between the glob-top material, the chip and the substrate material causes shear fractures on wire bonds and cracks on the substrate in case of thermal cycling. Generally, this is the case when glob-top is provided on a large area.

There have been attempts to use airfield microspheres made of glass as glob-top material. The air in the spheres reduces the dielectric constant for the glob-top. However, there are no commercially available products. The drawback of using high amount of glass is the increase of the viscosity, which obstructs the dispensing and wetting of chip, especially under the wire bonds. The wetting problem may result in air containments, which can explode during the curing process. Additionally, the glass beads result in an increase of elasticity coefficient of the material, which implies more mechanical stress on the wire bonds under thermal expansion.

U.S. Pat. No. 3,670,091 describes a compressible medium dispersed throughout a somewhat flexible matrix, so as to provide a pre-coat for encapsulated electrical components that reduces the stresses occurring thereon. The stresses relieved could be produced either from the component or from the outer encapsulant. The design of the system is such that the low pressures exerted during the application of the final coating do not substantially collapse or render useless the effective stress reducing characteristics of the intermediate pre-coat.

According to EP 807 971, an ultrahigh-frequency electronic component has an ultrahigh-frequency chip encased in a molded-resin package. The ultrahigh-frequency electronic component includes a first sealing layer encasing the ultrahigh-frequency chip therein and a second sealing layer encasing the first sealing layer therein. The first sealing layer contains a number of voids or minute air bubbles therein which are effective in reducing the permittivity of the first sealing layer. The sealing layer consists of resin containing air bubbles. The resin does not exhibit same characteristics as the material used according to the present invention, thus not fulfilling the advantages of the invention as mentioned below.

### SUMMARY OF THE INVENTION

Thus, the main object of the present invention is to provide a method and encapsulant that overcome the above-mentioned problems.

Other advantages of the invention will be appreciated when reading the following description.

For these reasons, the initially mentioned encapsulation arrangement consists of a plurality of expandable plastic particles, wherein each particle encapsulates a gaseous medium. Most preferably, said plastic particles expand when they are exposed to heat. The arrangement is part of a glob-top encapsulation. Preferably, said plastic particles are provided as microspheres or micro-balloons, which are easy to dispense. According to a preferred embodiment, said plastic material is a polymer.

For dispensing reasons the plastic particles encapsulating gas are provided in a die material. The plastic particles encapsulating gas are dispensed onto an encapsulation area by means of a dispenser. The plastic particles and die material are cured.

Preferably, the particles are expanded in a temperature range of 100° C. to 210° C., preferably from 110° C. to 190° C., and the curing temperature is from 100° C. to 210° C., preferably from 110° C. to 190° C.

The die material may consist of epoxies, silicones or phenols.

Preferably, the encapsulation arrangement is for electric component is a naked chip, which can be a microwave circuit for high frequencies.

The invention also refers to a method for encapsulating an electric component arranged on a carrying structure. The method comprises the steps of dispensing a plurality of plastic particles, each particle encapsulating gaseous medium, and heating said plastic particles to expand and cure.

### BRIEF DESCRIPTION OF THE DRAWINGS

In the following, the invention will be described in a non-limiting way with reference to the accompanying drawings, in which:

illustrate, in a schematic way, the steps of applying of an encapsulation arrangement according to the invention
illustrates a second example of the encapsulation according to the invention, and
illustrate schematically the expansion of microspheres in an encapsulant, according to the invention.

### DETAILED DESCRIPTION OF THE EMBODIMENTS

According to the invention, the encapsulation arrangement consists of gas field plastic (micro) beads or spheres instead of glass. Surprisingly, it has been observed that plastic microspheres used in the encapsulant have low dielectric constant, higher coefficient of fullness, low viscosity and lower elasticity coefficient.

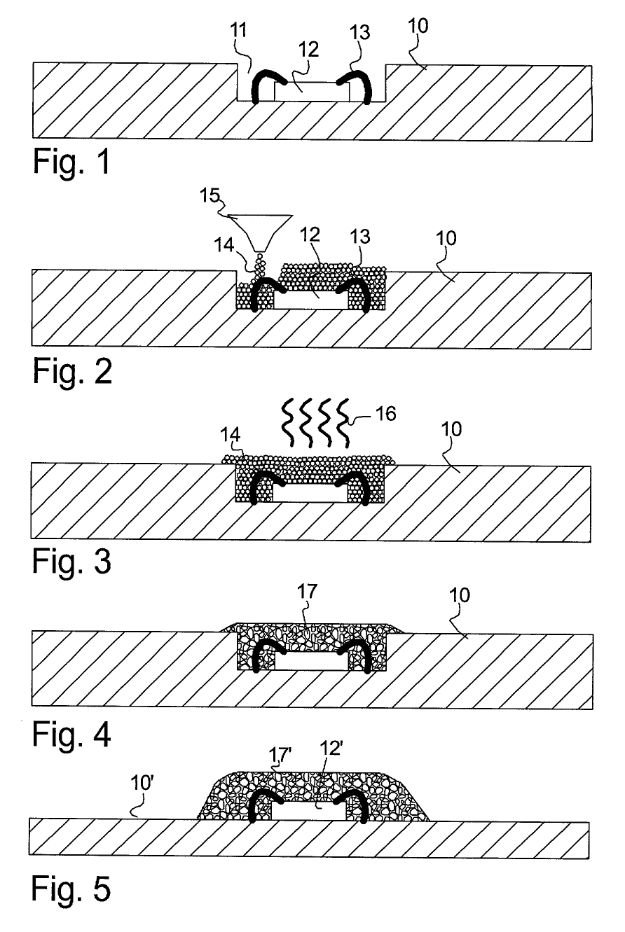

For better understanding of the features of the present invention, it is described in conjunction with illustrative examples shown in FIGS. 1-5. FIGS. 1 to 4 illustrate one example of the steps of applying and curing the encapsulation arrangement on a carrier structure.

FIG. 1 is a cross section through the carrier structure 10, such as a printed circuit board, a substrate or the like. A cavity 11 is arranged on one surface of the carrier 10 for receiving an electrical component 12, such as a circuit and particularly a naked circuit for microwave applications. The electric component is connected to circuit conductors (not shown) by means of wire bonds 13. The component is placed in the cavity and fixed, e.g. by means of an adhesive agent.

In FIG. 2, the glob-top material consisting of plastic, gas field microspheres 14 are dispensed pensed by means of a dispenser 15.

Examples of microspheres that can be used are:

EXPANCEL® (by Akzo Nobel), which comprises spherical plastic particles. The microspheres consist of a polymer shell encapsulating a gas. When the gas inside the shell is heated, it increases its pressure and the thermoplastic shell softens, resulting in a dramatic increase in the volume of the microspheres.

Dualite® and MICROPEARL™ (by Pierce & Stevens), which are heat expandable polymeric microspheres and expand to form a low-density sphere.

Of coarse, above products are given as examples and other plastic microspheres may also be used. Moreover, the invention is not limited to the spherical particles and particles having other shapes can also be used.

Microspheres can have different sizes for different applications; a typical diameter for non-expanded spheres is 1-50 μm, which are expanded to a diameter of 30-300 μm. Epoxies, silicones, phenols and similar material can be used as die material.

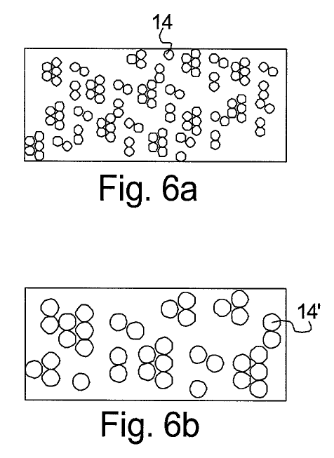

In FIG. 3, the dispensed microspheres are exposed to heat 16 or other radiation that generates heat resulting in expansion of spheres. The expansion and curing temperature may range from 100° C. to 210° C., preferably from 110° C. to 190° C. Most of microspheres have curing temperatures within the expansion temperature range. FIGS. 6a and 6b show, in a schematic way, the non-expanded and expanded micro spheres 14 and 14′, respectively, in the same section of the encapsulation.

FIG. 4 shows the final stage, where the encapsulation arrangement 17 has cured and seals the component.

In FIG. 5, another example is shown, in which a circuit 12′ is arranged directly on a substrate 10′, and provided with the encapsulation arrangement 17′ according to the invention.

The advantages of the encapsulation material according to the invention compared to glass spheres can be summarized by:

The expanded (and cured) material has a low dielectric coefficient, which results in low losses at high frequencies.

The small size of non-expanded particles allows a higher filling ratio, which also allows lower dielectric coefficient.

The small size of a particle also results in lower viscosity and reliable dispensing.

The plastic spheres have the advantage of not being crushed in the dispenser, e.g. a feed gear, because they are softer, smaller and more flexible.

The expanded spheres have lower elasticity module, which results in lower mechanical stress.

The stresses from the thermal mismatch are absorbed easier by the material with lower elasticity module; thus, fractures in the substrate and wire bonds can be avoided.

The invention is not limited to the shown embodiments but can be varied in a number of ways without departing from the scope of the appended claims and the arrangement and the method can be implemented in various ways depending on application, functional units, needs and requirements etc.

What we claim is:

1. An encapsulation arrangement for encapsulating an electric component arranged on a carrying structure, wherein said encapsulation arrangement consists of a plurality of expandable plastic particles, each particle encapsulating a gaseous medium.

2. The encapsulation arrangement of claim 1, wherein said plastic particles expand when they are exposed to heat.

3. The encapsulation arrangement of claim 1, wherein said arrangement is part of a glob-top encapsulation.

4. The encapsulation arrangement of claim 1, wherein said plastic particles are provided as microspheres or micro-balloons.

5. The encapsulation arrangement of claim 1, wherein said plastic material is a polymer.

6. The encapsulation arrangement of claim 1, wherein said plastic particles encapsulating gaseous are provided in a die material.

7. The encapsulation arrangement of claim 1, wherein said plastic particles encapsulating gaseous medium are dispensed onto an encapsulation area by means of a dispenser.

8. The encapsulation arrangement of claim 6, wherein said plastic particles and die material are cured.

9. The encapsulation arrangement of claim 1, wherein the expansion temperature of said particles ranges from 100° C. to 210° C., preferably from 110° C. to 190° C.

10. The encapsulation arrangement according claim 8, wherein the curing temperature ranges from 100° C. to 210° C., preferably from 110° C. to 190° C.

11. The encapsulation arrangement according claim 8, wherein said die material consists of epoxies, silicones or phenols.

12. The encapsulation arrangement of claim 1, wherein said electric component is a naked chip.

13. The encapsulation arrangement according claim 12, wherein said naked chip is a microwave circuit for high frequencies.

14. A method for encapsulating an electric component arranged on a carrying structure, the method comprising dispensing a plurality of plastic particles to a space for receiving said electric component, each encapsulating a gaseous medium, and heating said plurality of plastic particles to expand and cure, and encapsulate said electric component.
